(19) United States
(12) Patent Application Publication
(10) Pub. No.: US 2019/0019569 A1
(43) Pub. Date: Jan. 17, 2019

(54) ROW REPAIR OF CORRECTED MEMORY ADDRESS

(71) Applicant: Hewlett Packard Enterprise Development LP, Houston, TX (US)

(72) Inventor: Eric L Pope, Tomball, TX (US)

(21) Appl. No.: 16/066,392

(22) PCT Filed: Jan. 28, 2016
(86) PCT No.: PCT/US2016/015373

§ 371 Date: Jun. 27, 2018

(51) Int. Cl. G11C 29/00; G11C 29/44; G11C 29/52; G11C 29/46

(52) U.S. Cl. CPC G11C 29/808; G11C 29/44; G11C 2029/0409; G11C 29/46; G11C 2029/4402; G11C 29/52

(57) ABSTRACT

Addresses of memory cells that have errors corrected by error correction operations are evaluated to identify a failed row of memory. Post package repair is implemented on the failed row.

### BACKGROUND

Some random access memory (RAM) technologies, such as double data rate fourth generation synchronous dynamic RAM (DDR4), include post package repair (PPR) technology. With PPR, a row or memory, such as a failed row or a row under test, is remapped to a spare row. PPR can be used to repair DRAM failures that are isolated to a single memory cell or a single row of memory. PPR includes two modes: hard PPR, which is a permanent repair that persists across power cycles; and soft PPR, which is a temporary repair that persists until a power cycle or until the repair hardware is reprogrammed to repair a different location. Hard PPR is often used as a production feature to improve yields by remapping bad rows to built-in redundant rows. Soft PPR is often used as a validation feature by temporarily remapping a row to a spare during testing.

### BRIEF DESCRIPTION OF THE DRAWINGS

Certain examples are described in the following detailed description and in reference to the drawings, in which:

FIG. 1 illustrates an example method of implementing post package repair;

FIG. 2 illustrates an example of system operation showing transition from a single chip spare (SCS) mode to a double chip spare (DCS) mode and back after PPR;

FIG. 3 illustrates an example system for implementing PPR operations to repair failed rows;

FIG. 4 illustrates an example server including a BMC having an analyzer and controller for implementing PPR on rows having correctable errors; and

FIG. 5 illustrates an example system including a non-transitory computer readable medium storing instructions to implement a PPR operation on an identified failed memory row.

### DETAILED DESCRIPTION OF SPECIFIC EXAMPLES

Implementations of the disclosed technology use PPR to improve the effectiveness of error correction technology. For example, the described techniques may be used on systems with error correcting technology, such as Error Correction Code (ECC), Single Chip Spare (SCS), Double Chip Spare (DCS), or Advanced DCS (ADCS) memory. With ECC memory, a single bit error can be corrected and a two bit errors can be detected per word. With SCS memory, any number of errors on a single chip may be corrected up to failure of an entire chip. With DCS memory, up to two memory chips failures may be corrected. However, DCS operates by storing cache lines across multiple busses or multiple distinct ranges of memory addresses within a single bus. This incurs a bus bandwidth penalty as extra cycles are needed to configure reading from or writing to different busses or different ranges on a single bus. ADCS addresses this penalty by operating in either SCS mode or DCS mode based on the state of the memory. When a failure in a single chip occurs, the portion of the memory affected by the failure is converted to DCS mode. Portions of memory that are not affected remain operating in SCS mode.

Some implementations detect that errors are occurring and being corrected by the error correction systems. The errors are analyzed to determine if they are indicative of a row failure. If so, then a post package repair (PPR) operation is performed to replace the failed row with a spare row. This may restore the resiliency of the error correction system by reducing the number of errors occurring in the memory system. For example, an ECC memory system may be encountering single bit errors due to a failed row. Prior to the PPR, the system would be unable to correct an additional error occurring in another bit off the failed row. After the PPR, the errors due to the failed row no longer occur, so the ECC system is able to correct those previously uncorrectable additional errors. As another example, an ADCS memory system may be operating in DCS mode because of a row failure. After PPR, the system may be able to return to SCS mode.

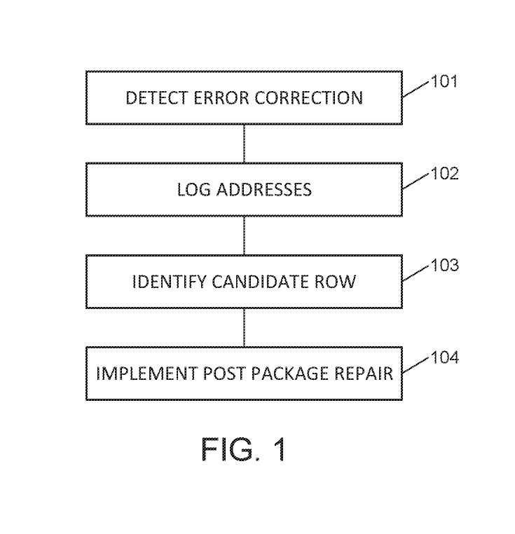

FIG. 1 illustrates an example method of implementing post package repair. In some implementations, the illustrated method may be performed by a server executing a program stored on a system read-only memory (ROM). For example, the method may be performed by a baseboard management controller (BMC) of a server. As another example, the method may be performed by a host system of the server.

The method may include block 101. Block 101 may include obtaining indications of error correction operations. For example, a memory controller or other hardware that performs the error correction operations may generate a notification, such as an interrupt, after an error occurs. Block 101 may include receiving such a notification. For example, the host system BIOS or the BMC may receive the interrupt. In some cases, the memory controller may store information regarding the error correction operations in an error log register. Block 101 may further include sampling such an error log register. For example, block 101 may include receiving an interrupt and sampling the error log register in response to the interrupt.

The method may include block 102. Block 102 may include logging addresses of memory cells having errors corrected by the error correction operations. For example, the host system BIOS or the BMC may perform block 102 by retrieving information regarding the corrected errors from the memory controller or other hardware performing the error correction operations. The retrieved information may include the addresses of corrected errors. For example, for single bit error corrections, the retrieved information may include the address of the corrected bit. For chip-level corrections, the retrieved information may include a range of addresses for the bits on the failed chip. In some implementations, block 102 may include logging the row addresses of the corrected errors. In other implementations, 102 the entire address of the corrected bit may be logged, or a different portion of the address of the corrected bit may be logged.

In some cases, block 102 may include logging errors that occur within certain time periods. For example, block 102 may include periodically clearing the log. For example, the log may be cleared on a daily, weekly, monthly, or some other basis. In some implementation, the periodicity may be configured by a management system. For example, the periodicity may be configured by issuing a command to the BMC or the host system operating system.

The method may include block 103. Block 103 may include tracking error patterns over a period of time to determine if there are commonalities in the error locations that indicate that some of the errors could be corrected using PPR. For example, block 103 may include evaluating the addresses to identify a candidate for PPR. For example, the candidate may be a failed row of memory. In some cases, the failed row of memory may not be a completely failed row. For example, some cells on the failed row may still reliably hold data but other cells may have permanent or repeating transient errors.

Block 103 may include identifying a set of addresses corresponding to failures on a common bank of a single DRAM chip. For this set, the row addresses of the failed bits may be identified from the addresses logged in block 102. In some implementations, a row may be identified as failed if more than a threshold number of errors share the row's address. In some cases, only unique error addresses may be counted when counting the number of errors. In other words, if an error occurs twice at the same bit address, then only one of the error events is counted. For example, only counting error corresponding to unique locations may avoid over weighting an error at a frequently accessed location. In still further cases, only errors that occur a certain number of times (such as twice) are counted. For example, counting only repeating errors may avoid unnecessarily performing row repair because of a one-time event such as a cosmic ray. In some implementations, each unique error location with a repeating error is counted to contribute to the threshold comparison. For example, a row might be identified as failed if the set includes more than the threshold number of repeated errors at unique locations. In other cases, all errors are counted for the threshold comparison. In some implementations, the configuration of which errors are counted and the threshold used to identify a failed row may be configured through the management system.

In some implementations, block 103 may further include evaluating the addresses according to when the errors occurred. For example, instead of clearing the log in block 102, block 103 may include evaluating only errors that occurred within a certain time. As another example, the threshold may vary depending when the errors occurred. For example, the threshold may be x if the errors occur within a first range of time t₁ and the threshold may be y if the errors occur within a second range of time t₂. For instance, row N may be identified as failed if 10 errors occur with row address N within a single day or 50 errors occur with row address N within a week.

As an example, block 103 may include accumulating a count of errors occurring on each row. Once a row's error count reaches a first threshold, the time to attain that threshold is determined. If the time is less than a time threshold, then the row is identified as failed. If the time is greater than the time threshold, then the threshold may be modified or the portion of the error log for that row may be cleared.

In some implementations, block 103 may further include verifying that the errors are fixable via row repair. For instance, block 103 may include inspecting other errors within the set collected in block 101 to determine if the row failure is a result of other types of errors. For example, an error at another location may cause rows with the same row address on different banks or different chips to fail. Such an error may not be correctable via PPR. In this example, block 103 may include verifying that errors are not occurring on different banks or different chips at the same row address as the identified row.

As another example, block 103 may include verifying that a chip or a sub-array of chip has not failed in its entirety. In these cases, there may be insufficient PPR resources to replace all of the failed rows of the chip or sub-array, and the PPR resources may be reserved for freeing subsequent ECC resources. For example, after a complete chip failure, a system operating in SCS mode may transition to DCS mode. If the available PPR resources are insufficient to recover the system back to the SCS mode, then the resources may be reserved for the future. For example, the resources may be reserved to allow the system to continue operating in DCS mode past another chip failure, where the later chip failure is localized to a single row or a few rows.

The method may further include block 104. Block 104 may include implementing a post package repair operation (PPR) on the failed row. In some cases, block 104 may include instructing a memory controller to perform the PPR. For example, the PPR may be a soft PPR or a hard PPR. If the PPR is a soft PPR and will persist across boot cycles, then a region of persistent memory may be used to cause the memory controller to perform the soft PPR during each boot cycle. For example, the memory may be on the system ROM, on the BMC, or in the memory controller. The type of PPR may depend on available resources. For example, the system may perform hard PPR until hard PPR resources have been exhausted. Afterward, if soft PPR resources remain, then future row failures may be corrected using soft PPR.

In some implementations, block 104 may include performing the PPR during the current system operation period. For example, block 104 may comprise instructing the memory controller to perform a soft PPR during the current boot cycle. In these implementations, error correction resources previously devoted to correcting errors occurring on the repaired row are freed and available for correcting errors at other locations during the current boot cycle.

In some implementations, block 104 may include scheduling the PPR to occur at a subsequent reboot. For example, block 104 may include scheduling the PPR to occur in the immediately following reboot cycle. In other implementations, block 104 may include scheduling the PPR to occur at a later reboot cycle. For example, block 104 may comprise checking a row previously identified as failed at a next boot cycle. If errors continue to occur on that row, then block 104 may include scheduling the PPR for the following boot cycle. In these implementations, error correction resource previously devoted to correcting errors occurring on the repaired row are freed and available for correcting errors during subsequent boot cycles. In further implementations, block 104 may include alerting the host system or system administrator that a PPR is scheduled for the subsequent reboot.

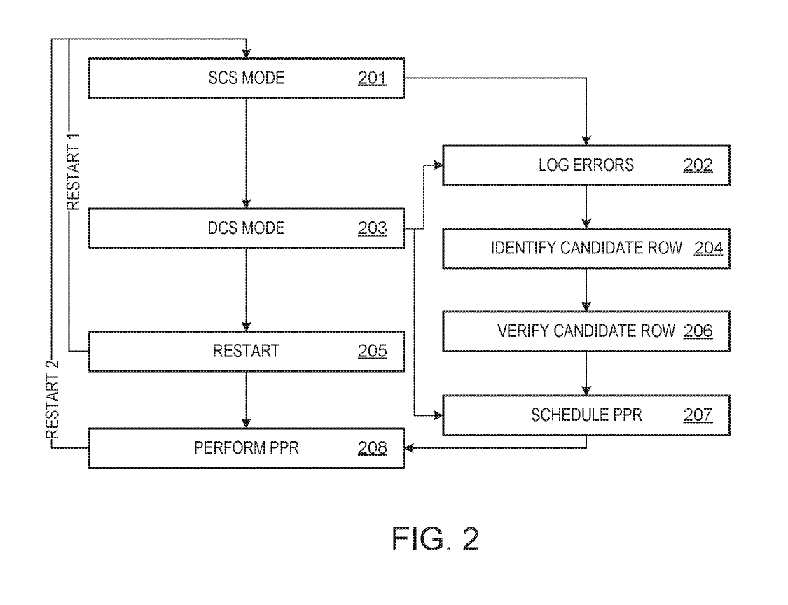

FIG. 2 illustrates an example of system operation showing transition from a single chip spare (SCS) mode to a double chip spare (DCS) mode and back after PPR.

Initially, the system operates in an SCS mode 201 where cache lines are stored in an SOS mode in the memory. For example, the memory controller 201 may encode cache lines using an appropriate SCS ECC and store the cache lines accordingly. For example, the memory controller 201 may store the encoded cache lines on the chips of a single rank such that the entire cache line is accessible on a single bus. For example, in a system with 18 chips on a rank, the cache line may be stored on 16 chips with 2 chips used for the ECC information. In the SCS mode, the system is able to continue running even in the presence of a single memory chip within an ECC code word. Accordingly, failure of a chip does not render a cache line stored in SCS mode unusable.

During operation in mode 201, the system may log errors 202. The system may log the errors as described with respect to block 101 of FIG. 1. For example, the memory controller may record error information in a designated log. As another example, the memory controller may send interrupts when errors occur, which trigger the host system or BMC to log the errors. As a further example, the host system or BMC may periodically observer error log registers on the memory controller to retrieve the error information, and then store the information in the log.

In the illustrated example, after operating in SCS mode 201 for some period of time, the system transitions to operating in DOS mode 203. For example, a row on a chip may fail causing the system to transition into the DOS mode 203. In the DOS mode 203, a different ECC code is used than in SCS mode and the memory controller spreads cache lines across more chips than in SCS mode. For example, in 18×4 chip layout described above, cache lines stored in DOS mode 203 may be spread across 36 chips. For example, the cache line may be divided between different ranks of the same memory module, different memory modules on the same channel, or different memory channels. During operation in DCS mode 203, the system may continue to log errors 202.

In some implementations, the system may operate in SCS mode 201 with respect to some memory regions and DCS mode 203 with respect to other regions. In these implementations, transitioning from mode 201 to mode 203 may be performed with respect a subset of the memory system. For example, the region transformed from SCS mode to DCS mode may be all addresses within a single bank of a single memory rank. As another example, a selectable set of rows may be transformed from SCS mode to DCS mode by sending a command to the memory controller.

At some time, the system evaluates the log to identify 204 a candidate row for PPR. For example, the system may periodically perform the evaluation at various scheduled times. As another example, the system may perform the evaluation in response to a trigger condition, such as the system entering the DCS mode 203. In some implementations, the identification process 204 may be performed as described with respect to block 103 of FIG. 1. In some cases, the identification process 204 may verify that repairing the row would eliminate the need to operate in DCS mode 203. Additionally, in implementations where a subset of the memory addresses on a bank have been transformed to DCS mode, the identification process may be restricted to inspecting only the subset transformed to DCS mode. For example, only errors corresponding to addresses within the subset might be retrieved from the error log.

After identifying a candidate row, the system may schedule a PPR operation 206 to occur on a subsequent reboot. In the illustrated example, the system schedules the PPR operation 206 to occur after a second restart 205.

After a first restart 205, the system returns to operation in SCS mode 201 and continues to log errors 202. If the system enters DCS mode 203 again, then the system verifies 206 that the candidate row identified in block 204 continues to be subject to errors. If so, then the system schedules a PPR operation 207. For example, the system may schedule the PPR operation 207 as described with respect to block 104 of FIG. 1. If the verification 206 fails, then the system may return to block 204 to identify a new candidate row.

After a subsequent restart 205 after scheduling 207, the system performs the PPR operation 208. After the PPR operation, the errors causing the entry into DCS mode 203 may be eliminated, and the system may remain in SCS mode 201 as normal. Accordingly, the PPR operation may restore the system to its normal operational mode. Even if the PPR operation fails to cure the error causing the system to enter DCS mode 203, the PPR operation may improve the robustness of the memory addresses corresponding to the repaired row.

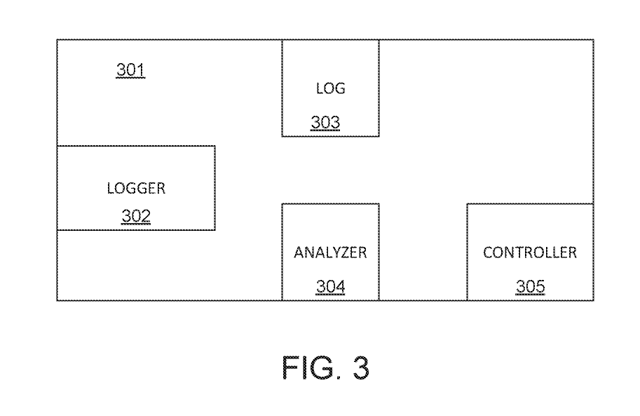

FIG. 3 illustrates an example system 301 for implementing PPR operations to repair failed rows. The illustrated components may be implemented as hardware, software stored on a non-transitory computer readable medium and executed by a processor, or a combination thereof. In some cases, the system 301 may be contained within a server component. For example, the system 301 may be a baseboard management controller. In other cases, the system 301 may be disturbed throughout the components of a server.

The system 301 includes a log 303 to store addresses of memory cells having errors corrected through error correction operations. In some cases, the log 303 is stored in a manner that is persistent across reboots. For example, the log 303 may be stored in a region of non-volatile memory such as flash memory on a BMC or in the host system's storage. In some implementations, the memory controller may log error correction information directly in the log 303. In other implementations, a logger 302 may retrieve the information from the memory controller and store it in the log. For example, the logger 302 may periodically query error log registers of the memory controller or query the error log registers after the memory controller generates an interrupt upon correcting an error.

The system 301 includes an analyzer 304 to use the log to identify a row that is repairable via post package repair. For example, the analyzer 304 may be implemented by a BMC controller executing an analyzer program. As another example, the analyzer 304 may be an ASIC or other hardware component connected to the log 304 and controller 305. The identified row may comprise at least a portion of the memory cells having addresses within the log. For example, the analyzer 304 may perform block 103 of FIG. 1 to identify the repairable row. In various implementations, the analyzer 304 may perform the identification on a schedule, as a result of triggering conditions, or upon a system command. For example, the analyzer 304 may run on a daily, weekly, or monthly schedule. As another example, the analyzer 304 may run in response to an ADCS transitioning from SCS to DCS mode, or in response to an SCS system detecting an error effecting an entire chip.

As a further example, the analyzer 304 may run in response to the log 303 collecting a threshold number of errors. In some cases, the log 303 or analyzer 304 may maintain different counts for different regions of memory. for example, the analyzer 304 may have counts for ranks, banks, or channels.

The system 301 may further comprise a controller 305 to implement a post package repair operation to repair the row. For example, the controller 305 may be implemented by a PPR implementation program running on a BMC controller, memory controller, or host system. The controller 305 may implement the PPR operation as described above with respect to block 104 of FIG. 1. For example, the controller 305 may communicate with a memory controller to schedule a PPR operation for a subsequent reboot. As another example, the controller 305 may communicate with the memory controller to implement a PPR operation during a current operating period. As a further example, the controller 305 may communicate directly with the memory to perform the PPR operation.

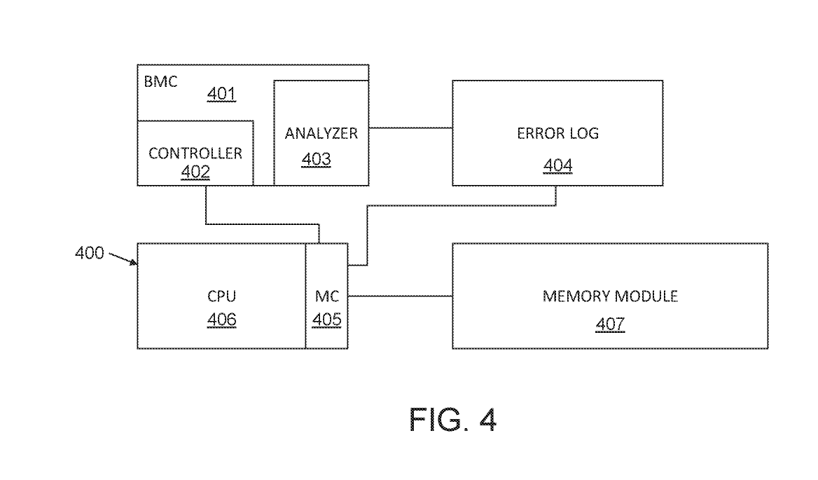

FIG. 4 illustrates an example server including a BMC 401 having an analyzer 403 and controller 402 for implementing PPR on rows having correctable errors. In some implementations, the analyzer 403 and controller 402 may be implemented on an ASIC or executed by an embedded processor on the BMC 401. For example, the illustrated system may be an implementation of a system as described with respect to FIG. 3.

The system includes a host server 400 including a central processing unit (CPU) 206, memory controller 405, and memory module 407. For example, the memory module 407 may be a dual inline memory module (DIMM) coupled to the memory controller 405 over a Double Data Rate (DDR) interface such as DDR4. The memory controller 405 performs error correction encoding and decoding on data stored on the memory module 407. For example, the memory controller 405 may use any of the ECC schemes described above.

The system further includes an error log 404. The error log 404 may store information regarding locations of errors that have been corrected by the memory controller. In some implementations, the error log 404 may retrieve the error information from the memory controller 405. For example, the error log 404 may poll the memory controller 405 or the memory controller 405 may transmit the information to the error log 404. In other implementations, the BMC 401 may manage the error log 404. For example, the BMC 401 may retrieve the error information from the memory controller 405 or the memory controller 405 may transmit the error information to the BMC 401. When the BMC 401 obtains the error information, it stores it in the error log 404.

In this implementation, the BMC 401 includes an analyzer 403. The analyzer 403 may operate as described with regard to analyzer 304 of FIG. 3. As described above, the analyzer 403 may inspect the error log to identify recurring errors that would be correctable via a PPR operation.

The BMC 401 further includes a controller 402. The controller 402 may operate as described with respect to controller 305 of FIG. 3. For example, the controller 403 may instruct the memory controller 402 to implement a PPR operation. As another example, the controller 403 may configure the host system 400 to implement the PPR operation. For example, the controller 403 may instruct a host system to implement the PPR operation. For example, the controller 403 may configure the operating system to implement the PPR operation.

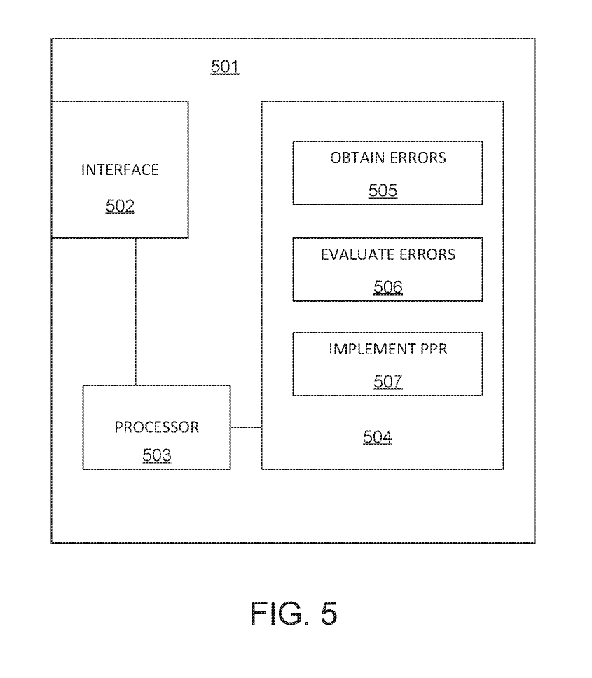

FIG. 5 illustrates an example system 501 including a non-transitory computer readable medium 504 storing instructions to implement a PPR operation on an identified failed memory row. For example, the medium 504 may be a host system's or BMC's read only memory (ROM). As another example, the medium 504 may be system RAM, or flash memory.

The system 501 may include a processor 503 and an interface 502. For example, the processor 503 may be a host system processor and the interface 502 may be an interface to system RAM. For example, the interface 502 may be an interface to a memory controller. As another example, the system 501 may be a BMC, where the processor 503 is an embedded processor and the interface 502 may be an interface to a system processor or memory controller via a platform controller hub.

The medium 504 stores instructions 505 executable by the processor 503 to obtain a set of memory addresses of correct errors. For example, the instructions 505 may be executable to obtain the set of memory addresses from a log of memory errors or from a memory controller. In some cases, the instructions 505 are executable to obtain the set by selecting memory addresses on a common DRAM chip from a log of memory addresses of corrected errors.

The medium 504 stores further instructions 506 executable by the processor 503 to evaluate the set of errors to identify a failed row. In some cases, the instructions 506 may be executable by the processor 503 to perform block 103 of FIG. 1. For example, the instructions 506 may be executable to identify the failed row by identifying a row address shared by at least a portion of the set of memory addresses.

The medium 504 stores further instructions 507 executable by the processor 503 to implement a PPR operation on the identified failed row. In some cases, the instructions 507 may be executable by the processor 503 to perform block 104 of FIG. 1. For example, the instructions 507 may be executable to instruct a memory controller to perform a soft PPR operation during a current operational period and to schedule a hard PPR operation for a subsequent boot cycle.

In the foregoing description, numerous details are set forth to provide an understanding of the subject disclosed herein. However, implementations may be practiced without some or all of these details. Other implementations may include modifications and variations from the details discussed above. It is intended that the appended claims cover such modifications and variations.

1. A method, comprising:
obtaining indications of error correction operations;
logging addresses of memory cells having errors corrected by the error correction operations;
evaluating the addresses to identify a failed row; and
implementing a post package repair operation on the failed row.

2. The method of claim 1, wherein the obtaining comprises:
receiving interrupts caused by error correction operations.

3. The method of claim 1, wherein the obtaining comprises:
sampling an error log register.

4. The method of claim 1, wherein the implementing comprises:
scheduling the post package repair operation to occur at a subsequent reboot.

5. The method of claim 4, wherein the post package repair operation comprises a hard post package repair if available and comprises a soft post package repair if a hard post package repair is not available.

6. The method of claim 1, wherein the implementing comprises:
instructing a memory controller to perform the post package repair operation during a current system operation period.

7. A system, comprising:
a log to store addresses of memory cells having errors corrected through error correction operations;
an analyzer to use the log to identify a row that is repairable via post package repair, the row comprising at least a portion of the memory cells having addresses within the log; and
a controller to implement a post package repair operation to repair the row.

8. The system of claim 7, wherein the log is persistent across reboots.

9. The system of claim 7, further comprising a log manager to clear the log if a sufficient number of errors were not received in a sufficient time.

10. The system of claim 7, further comprising a baseboard management controller comprising the analyzer and the controller.

11. The system of claim 7, wherein the controller is to implement the post package repair operation by instructing a memory controller to perform the post package repair operation.

12. A non-transitory computer readable medium storing instructions to:
obtain a set of memory addresses of corrected errors;
evaluate the set of errors to identify a failed row; and
implement a post package repair operation on the failed row.

13. The non-transitory computer readable medium of claim 12, storing further instructions to:
obtain the set by selecting memory addresses on a common dynamic random access memory (DRAM) chip from a log of memory addresses of corrected errors.

14. The non-transitory computer readable medium of claim 13, storing further instructions to identify the failed row by identifying a row address shared by at least a portion of the set of memory addresses.

15. The non-transitory computer readable medium of claim 12, storing further instructions to implement the post package repair operation by:
instructing a memory controller to perform a soft post package repair operation during a current operational period, and
scheduling a hard post package repair operation for a subsequent boot cycle.
